(19) United States
(12) Patent Application Publication
(10) Pub. No.: US 2025/0142781 A1
(43) Pub. Date: May 1, 2025

(54) System For Utilizing Heating and Cooling Pads

(71) Applicant: I-SYST inc., Brossard (CA)

(72) Inventors: Nguyen Hoan Hoang, Brossard (CA); Duy Thinh Tran, Brossard (CA)

(73) Assignee: I-SYST inc., Brossard (CA)

(21) Appl. No.: 18/923,377

(22) Filed: Oct. 22, 2024

Related U.S. Application Data
(60) Provisional application No. 63/594,158, filed on Oct. 30, 2023.

(51) Int. Cl. H05K 7/20; H04M 1/72412

(52) U.S. Cl. CPC H05K 7/2039; H04M 1/72412

(57) ABSTRACT

A system for utilizing heating and cooling pads that are in different system configurations. The overall system includes one or more heating and cooling pads, a power supply such as a battery, and mobile and cloud-based applications. The overall system includes a flexible thermoelectric device and a controlling module with or without an integrated power source such as a battery. The overall system is in a standalone configuration if a power source is integrated into the control module and is in a meshed configuration when powered by an external power source. The mobile and cloud-based applications include mobile User Interfaces or UIs that include one or more monitoring UIs and one or more control UIs. The mobile and cloud-based applications include a mobile app or a cloud computing infrastructure.

### CROSS-REFERENCE TO RELATED APPLICATIONS

This U.S. Non-Provisional Patent Application claims the benefit of U.S. Provisional Patent Application No. 63/111,464 filed on Oct. 30, 2023. The above identified patent application is herein incorporated by reference in its entirety to provide continuity of disclosure.

### BACKGROUND OF THE INVENTION

The present invention is related to a system. More specifically, the present invention is related to a system for utilizing heating and cooling pads.

The Internet has changed many things in our everyday lives. Certainly client/server technology has affected the way people do everyday business.

However, that same client/server technology is now even affecting the way basic appliances and devices operate. This even includes the application of basic appliances and devices which may be tied into the Internet and other communication networks.

What is needed is a system for utilizing heating and cooling pads for a smart and flexible heating-cooling system, especially a wearable heating-cooling system, that is capable of intelligently optimizing heating performance and energy consumption that are in a plurality of different system configurations.

In addition to the heating and cooling purpose, the heating and cooling pad in the present invention is capable of electrical energy harvesting when the environmental condition is suitable. The harvested energy is then reused in the heating/cooling mode, thereby further saving energy consumption. The switch between the heating/cooling mode and the electrical energy harvesting mode is automatically conducted by the controlling module embodied in each heating and cooling pad.

### SUMMARY OF THE INVENTION

In view of the foregoing disadvantages inherent in the known types of systems for utilizing heating and cooling pads now present in the prior art, the present invention is a system for utilizing heating and cooling pads, wherein each heating and cooling pad includes a flexible thermoelectric device, a controlling module with a power source (e.g., a battery) or with a power socket for connecting with an external power supply, and a plurality of mobile and cloud-based applications.

It is an object of the present invention to provide a system for utilizing heating and cooling pads that provides versatile and friendly User Interfaces or UIs, thanks to a plurality of mobile applications and cloud-based software, for users to remotely monitor and customize heating and cooling performance of the system.

It is a further object of the present invention to provide a system for utilizing heating and cooling pads that includes the capability to harvest electrical energy wherein the present system converts temperature difference between the hot and cold sides of the heating and cooling pad to electrical energy and stores that energy within the power repository such as a battery or a super capacitor.

It's an object of the present invention to provide a system for utilizing heating and cooling pads that includes the capability to exchange data with other devices such as one or more external sensor devices.

It's an object of the present invention to provide a system for utilizing heating and cooling pads that includes Artificial Intelligence or AI-based decision making capabilities, e.g., anomaly detection, hazardous event prediction, and cooling and heating performance adjustment, thus improving the safety and convenience for users.

### BRIEF DESCRIPTION OF THE DRAWINGS

Although the characteristic features of this present invention will be particularly pointed out in the claims, the present invention itself and way it may be made and used may be better understood after a review of the following description, taken in connection with the accompanying drawings wherein like numeral annotations are provided throughout.

FIG. 1 shows a system overview of an embodiment of a system for utilizing a plurality of heating and cooling pads.

FIG. 2 shows an embodiment of a heating and cooling pad and its internal components of a system for utilizing a single or plurality of heating and cooling pads.

FIG. 3 shows a front perspective view and a rear perspective view of an embodiment of a first heating and cooling pad of a system for utilizing a plurality of heating and cooling pads.

FIG. 4 shows a front perspective view and a rear perspective view of an embodiment of a second heating and cooling pad of a system for utilizing a plurality of heating and cooling pads.

FIG. 5 shows an embodiment of a smart battery pack and its internal components of a system for utilizing a plurality of heating and cooling pads.

FIG. 6 shows an embodiment of a plurality of first mobile user interfaces of a mobile application communicating with a heating and cooling pad of a system for utilizing a plurality of heating and cooling pads.

FIG. 7 shows an embodiment of a plurality of first mobile user interfaces of a mobile application communicating with a plurality of heating and cooling pads of a system for utilizing a plurality of heating and cooling pads.

FIG. 8 shows an embodiment of a plurality of proprietary mobile and cloud-based applications wirelessly communicating with a plurality of standalone heating and cooling pads of a system for utilizing a plurality of heating and cooling pads.

FIG. 9 shows an embodiment of a plurality of proprietary mobile and cloud-based applications wirelessly communicating with a meshed network of a plurality of heating and cooling pads and a smart battery pack of a system for utilizing a plurality of heating and cooling pads.

FIG. 10 shows an embodiment of a cloud-based application wirelessly communicating with a meshed network of a plurality of heating and cooling pads and a smart battery pack of a system for utilizing a plurality of heating and cooling pads.

FIG. 11 shows an embodiment of a virtual reality headset of a system for utilizing a plurality of heating and cooling pads.

FIG. 12 shows an embodiment of a helmet of a system for utilizing a plurality of heating and cooling pads.

FIG. 13 shows an embodiment of a head band of a system for utilizing a plurality of heating and cooling pads.

FIG. 14 shows an embodiment of a head band of a system for utilizing a plurality of heating and cooling pads.

### DETAILED DESCRIPTION OF THE INVENTION

Reference is made herein to the attached drawings. Like reference numerals are used throughout the drawings to depict like or similar elements of the system for utilizing a plurality of heating and cooling pads. The figures are intended for representative purposes only and should not be considered to be limiting in any respect.

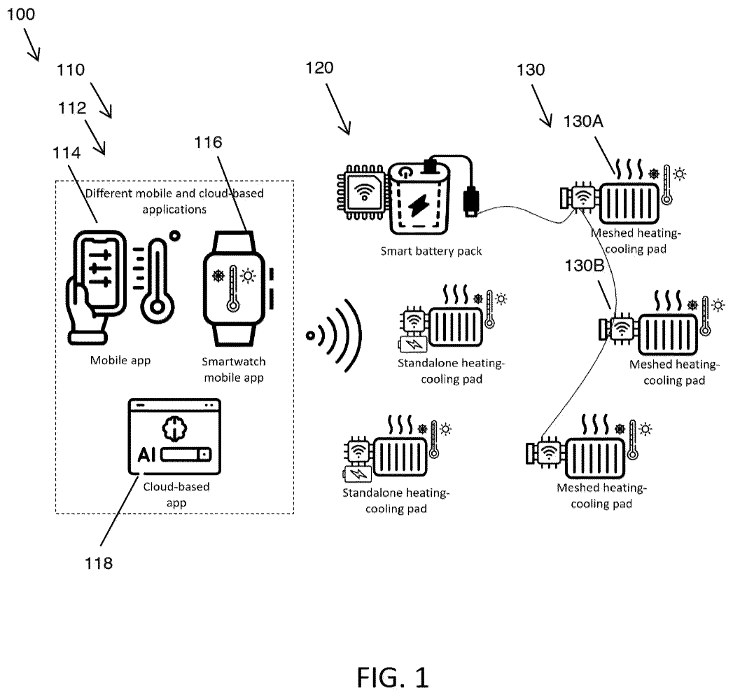

FIG. 1 shows a system overview of an embodiment of a system for utilizing a plurality of heating and cooling pads 100.

The overall system 100 may include a plurality of mobile applications 110, a smart battery pack 120, and one or more heating and cooling pads 130.

The mobile applications 110 may include a plurality of mobile and cloud-based applications 112 or the like that may wirelessly communicate with the one or more heating and cooling pads 130 in standalone and meshed configurations or the like. The mobile applications 110 may include a smart phone mobile app 114, a smart watch app 116, and a cloud-based app 118 and the like.

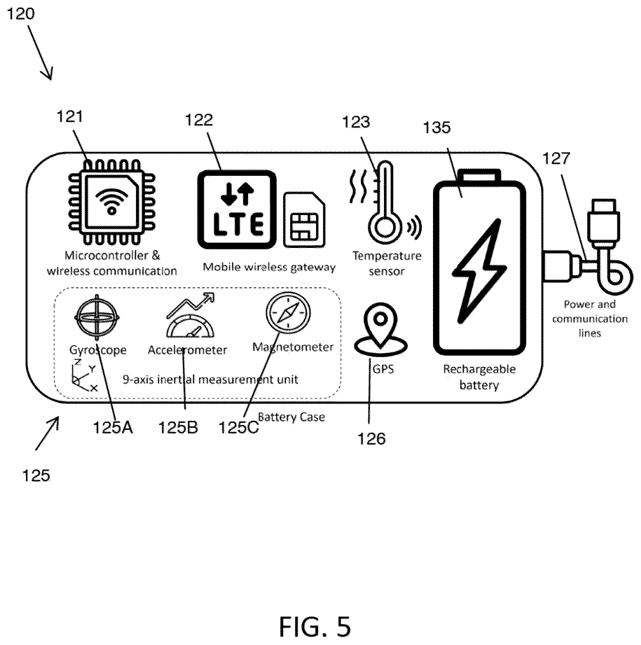

The smart battery pack 120, as additionally described in FIG. 5, may be in wired connection with the one or more heating and cooling pads 130 to supply electrical power and provide data communication with the mobile application 110, to the one or more heating and cooling pads 130.

The smart battery pack 120 may be in wireless communication with the mobile applications 110, enabling the mobile applications 110 to monitor and control the one or more heating and cooling pads 130 associated with the smart battery pack 120. Specifically, the smart battery pack 120 works as an intermediary relaying data exchanged between the one or more connected heating and cooling pads 130 and the mobile applications 110.

The one or more heating and cooling pads 130 may be in wireless communication with the mobile applications 110, allowing the mobile applications 110 to monitor temperature and other sensor data and control the thermal performance of the one or more heating and cooling pads 130 based on user preference.

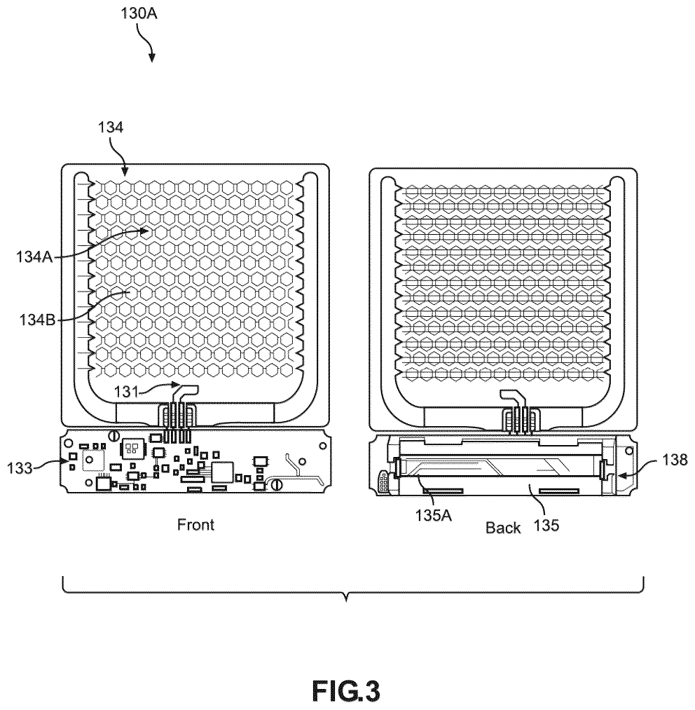

The one or more heating and cooling pads 130 may be in the configuration of one or more first heating and cooling pads 130A, which may be self-powered as additionally described in FIG. 3. The one or more first heating and cooling pads 130A in this configuration are referred to as a plurality of standalone heating and cooling pads or the like.

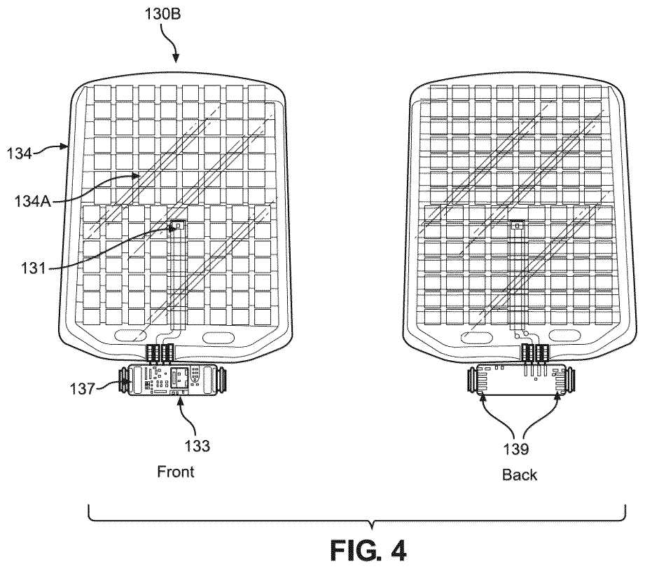

The one or more first heating and cooling pads 130A may also be in the configuration of one or more second heating and cooling pads 130B daisy-chained together, all of which may be powered by the smart battery pack 120 as additionally described in FIG. 4. The one or more second heating and cooling pads 130B in this configuration are referred to as a meshed network of heating and cooling pads or the like.

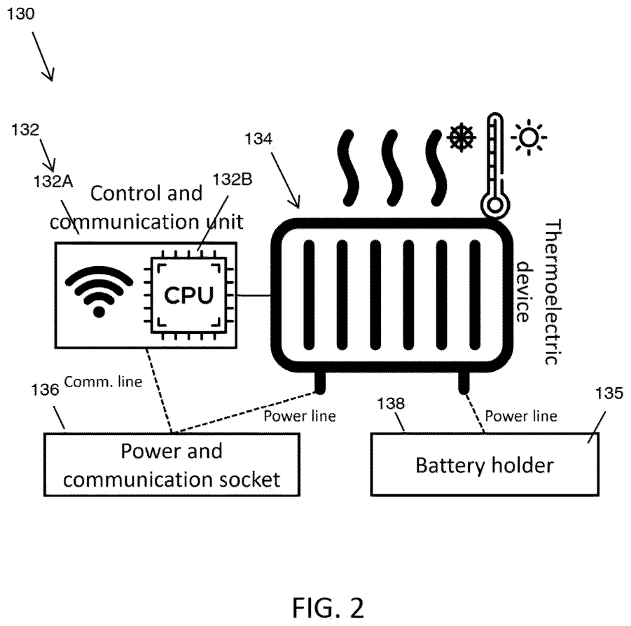

FIG. 2 shows a system overview of the main components of one or more heating and cooling pads 130 of the overall system 100 for utilizing the one or more heating and cooling pads 130.

The one or more heating and cooling pads 130 may include a control and communication unit 132, a flexible thermoelectric device 134, a power and communication socket 136, and a battery holder 138.

The control and communication unit 132 may include a communication module 132A and a central processing unit 132B. The control and communication unit 132 may control the heating and cooling performance, i.e., the thermal performance of the flexible thermoelectric device 134. The control and communication unit 132 may be in wireless communication with the mobile applications 110.

The flexible thermoelectric device 134 may be capable of electrical energy harvesting when the environmental condition is suitable. The harvested energy is then reused in the heating and cooling mode, thereby further saving energy consumption. The power and communication socket 136, equipped on the one or more second heating and cooling pads 130B shown in FIG. 4, is for wire communication with the smart battery pack 120. The battery holder 138 equipped on the one or more first heating and cooling pads 130A shown in FIG. 3, may contain a battery 135 or the like.

FIG. 3 shows a front perspective view and a rear perspective view of an embodiment of the configuration of the one or more first heating and cooling pads 130A of a system for utilizing a plurality of heating and cooling pads 100.

The one or more second heating and cooling pads 130A may include the flexible thermoelectric device (FIG. 2, 134), a temperature sensor 131, a control and communication module (FIG. 2, 133) which includes a control and communication unit (FIG. 2, 132) and the battery holder (FIG. 2, 138).

The flexible thermoelectric device 134 may include one or more heating elements 134A and/or one or more cooling elements 134B. The temperature sensor 131 may be disposed underneath each of the one or more heating and cooling pads 130. The control and communication module 133 may be disposed between each of the flexible thermoelectric devices 134 and each of the temperature sensors 131. The battery holder 138 may contain the battery 135, which may be a rechargeable battery 135A or the like that is disposed on the control and communication module 133.

These are the same features that have been described in FIG. 2 and its description of the one or more heating and cooling pads 130.

FIG. 4 shows a front perspective view and a rear perspective view of an embodiment of the configuration of the one or more second heating and cooling pads 130B of a system for utilizing a plurality of heating and cooling pads 100.

The one or more second heating and cooling pads 130B may include the flexible thermoelectric device 134, the temperature sensor 131, the control and communication module 133, a proprietary power and communication connector 137, and a plurality of connecting pads 139.

The flexible thermoelectric device 134 may be disposed on top of each of the one or more second heating and cooling pads 130B. The proprietary power and communication connector 137 may be disposed on the control and communication module 133. The connecting pads 139 may be disposed on the proprietary power and communication connector 137.

FIG. 5 shows an embodiment of the smart battery pack 120 and other internal components of a system for utilizing a plurality of heating and cooling pads 100.

The internal components of a smart battery pack 120 may include a microcontroller and wireless communication module 121, a mobile wireless gateway 122, a sensor 123, the battery 135, an inertial measurement unit or IMU 125, a Global Positioning System or GPS 126, and one or more communication lines 127.

The microcontroller and wireless communication module 121 may be for managing the operation of the smart battery pack 120 and for wirelessly communicating with the mobile applications on user mobile devices, e.g., mobile phones and smart watches (all not shown). The mobile wireless gateway 122 may connect to a mobile wireless network (not shown), allowing the smart battery pack 120 to communicate with the cloud-based applications. The sensor 123 may be a temperature sensor 123A or the like. The battery 135 may be a rechargeable battery 135A or the like. The IMU 125 may include a gyroscope 125A, an accelerometer 125B, and a magnetometer 125C. The GPS 126 may provide precise location and time information regarding the one or more heating and cooling pads 130. The one or more communication lines 127 may supply power and communicate with one or more of the connected heating and cooling pads 130.

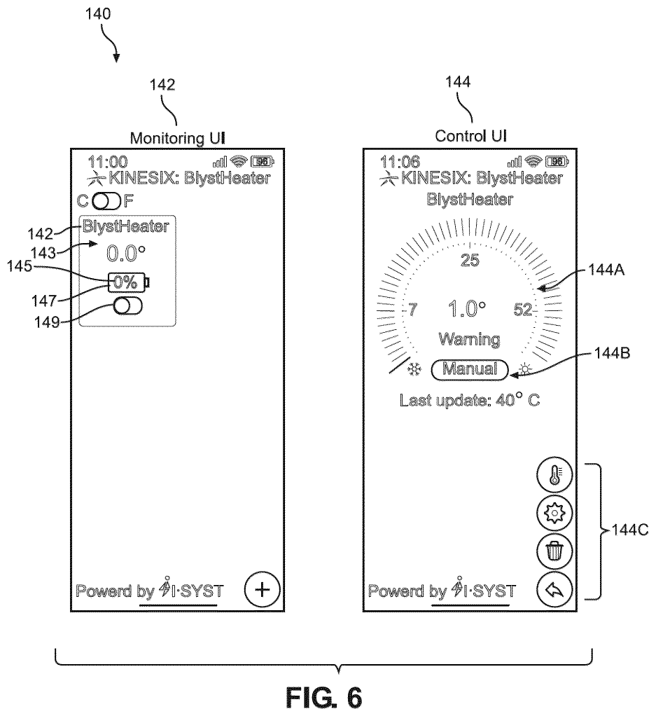

FIG. 6 shows an embodiment of a plurality of first mobile user interfaces 140 of a mobile application of a first plurality of heating and/or cooling pads 130A of a system for utilizing a plurality of heating and cooling pads 100.

The first mobile user interfaces 140 of the mobile application may include a monitoring mobile user interface 142 and a control mobile interface 144.

The monitoring mobile user interface 142 may include a temperature reading 143 for the plurality of first heating and/or cooling pads 130A of a system for utilizing a plurality of heating and cooling pads 100.

The monitoring mobile user interface 142 may include a battery charge percentage 145 disposed within a battery icon 147 of the monitoring mobile user interface 142 and a digital toggle switch button 149 to turn the connected heating and cooling pad 130 on and off.

The control mobile interface 144 may include a temperature control gauge 144A, a temperature control mode 144B, and a plurality of feature buttons 144C.

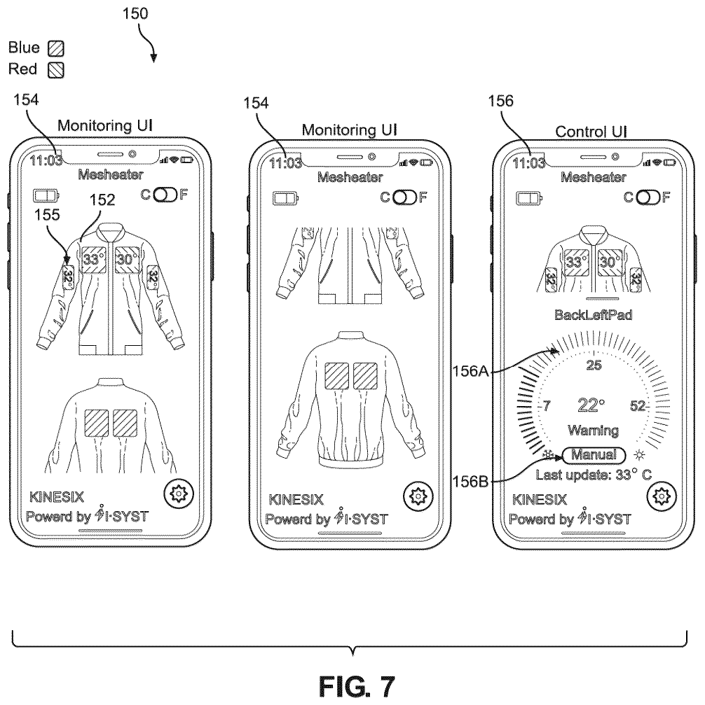

FIG. 7 shows an embodiment of a plurality of second mobile user interfaces 150 of a mobile app of a second plurality of heating and cooling pads 130B of a system for utilizing a plurality of heating and cooling pads 100.

The second mobile user interfaces 150 may include the same information as the first mobile user interfaces 140, except the second mobile user interfaces 150 are disposed on various items such as a piece of clothing 152 and the like.

The second mobile user interfaces 150 may include a pair of monitoring User Interfaces or UIs 154 and a pair of control UI 156.

The pair of monitoring user interfaces 154 may include a plurality of temperature display zones 155 disposed on the piece of clothing 152. The control UI 156 may include a temperature control gauge 156A and a temperature control mode 156B that is associated with the piece of clothing 152 and the temperature display zones 155.

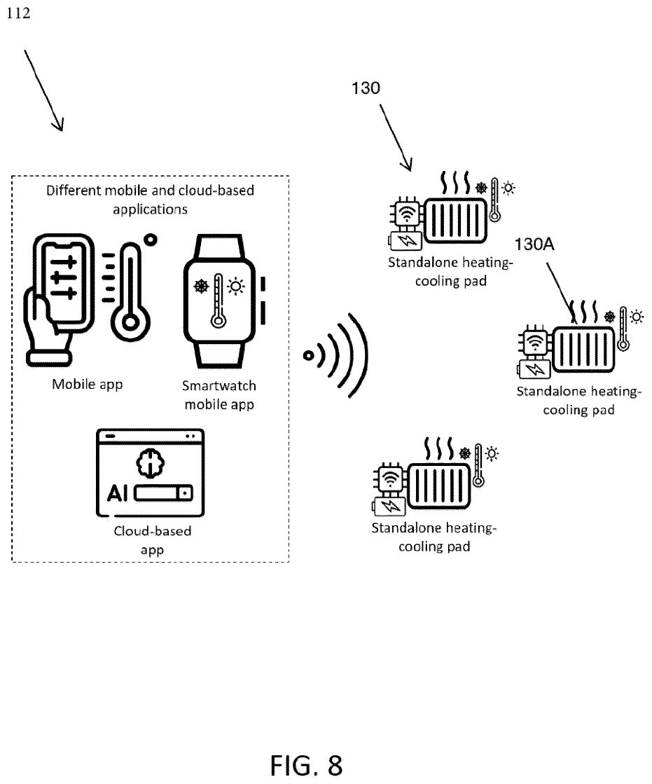

FIG. 8 shows an embodiment of a plurality of proprietary mobile and cloud-based applications (FIG. 1, 112) wirelessly communicating with the standalone heating and cooling pad 130, i.e., the first heating and cooling pad 130A shown in FIG. 3, of a system for utilizing one or more heating and cooling pads 100.

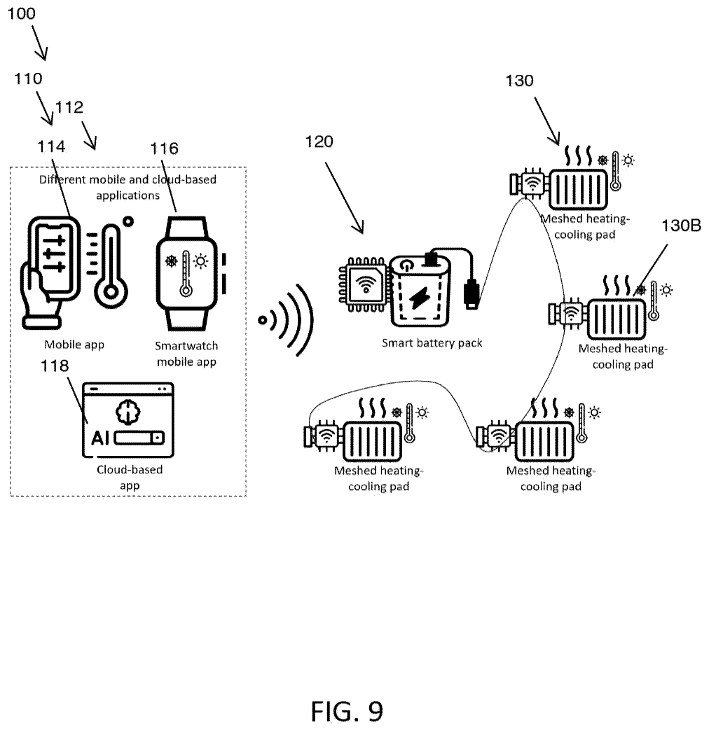

FIG. 9 shows an embodiment of a plurality of proprietary mobile and cloud-based applications (FIG. 1, 112) wirelessly communicating with the meshed heating and cooling pads, i.e., the second heating and cooling pads 130 shown in FIG. 4, or a system for utilizing a plurality of heating and cooling pads 100 and a smart battery pack 120.

The overall system 100 may include a plurality of mobile applications 110, a smart battery pack 120, and one or more heating and cooling pads 130.

The mobile applications 110 may include a plurality of mobile and cloud-based applications 112 or the like that may wirelessly communicate with the one or more heating and cooling pads 130 in standalone and meshed configurations or the like. The mobile applications 110 may include a smart phone mobile app 114, a smart watch app 116, and a cloud-based app 118 and the like.

The smart battery pack 120 may provide electrical power to the one or more meshed heating and cooling pads, i.e., the one or more second heating and cooling pads 130B in FIG. 4. The smart battery pack 120 may wirelessly communicate with the mobile and cloud-based applications 112 to provide data gathered from the connected one or more heating and cooling pads 130B, and to obtain control data from the other mobile and cloud-based applications 112 for controlling the one or more connected heating and cooling pads 130B.

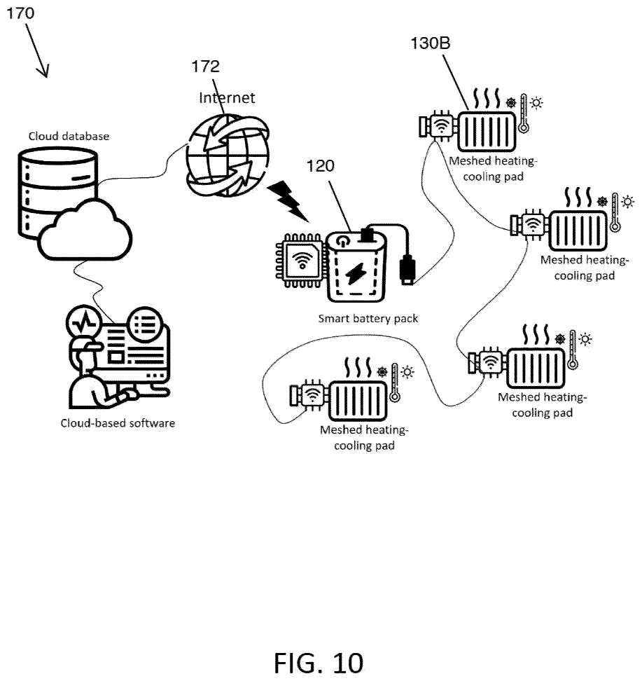

FIG. 10 shows an embodiment of a cloud-based application 170 communicating with the smart battery pack 120 to control and monitor the operation of the second one or more heating and cooling pads 130B of a system for utilizing a plurality of heating and cooling pads 100 and a smart battery pack 120.

The smart battery pack 120 may be in wireless communication with a cloud-based application 170 via the Internet provided by a mobile wireless network 172, thereby enabling the cloud-based application 170 to control and monitor the operation of the one or more second plurality of heating and cooling pads 130B.

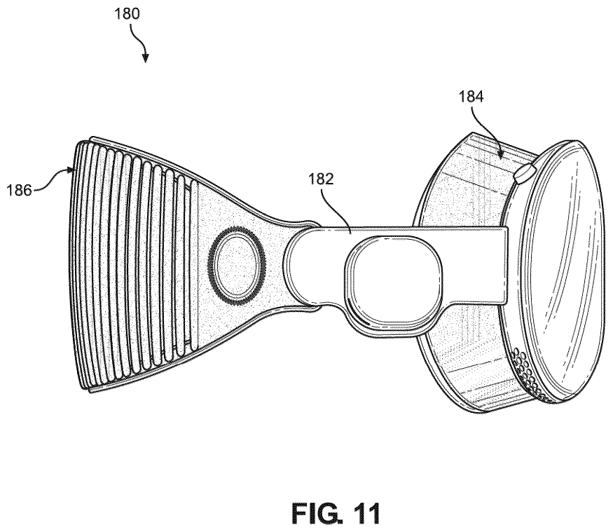

FIG. 11 shows a side perspective view of a virtual reality headset 180 of a system for utilizing a plurality of heating and cooling pads 130.

The virtual reality headset 180 may include a back handle 182 and one or more cooling and heating pads 184 that cools down a user's forehead and eyes and would improve the user's comfort and user experience. The one or more cooling and heating pads 184 may be disposed directly behind a virtual reality headset 180 configured to be in physical contact with a user's forehead or the like and disposed on a backward extending handle 186 extending behind the user's head.

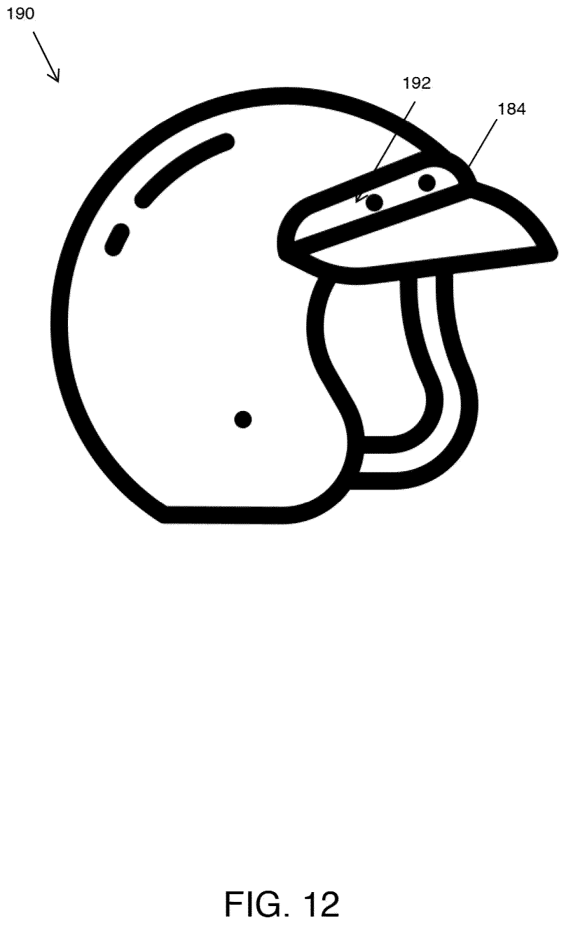

FIG. 12 shows a side perspective view of a helmet 190 of a system for utilizing a plurality of heating and cooling pads 100.

The helmet 190 may include the one or more cooling and heating pads 184 disposed directly onto the outer surface of the helmet 190 to facilitate cooling a user's head while being worn by the user. The one or more cooling and heating pads 184 (having a different shape of the cooling and heating pads 130) may be disposed on a headband 192 within the helmet 190 to facilitate cooling a user's head while being worn by the user.

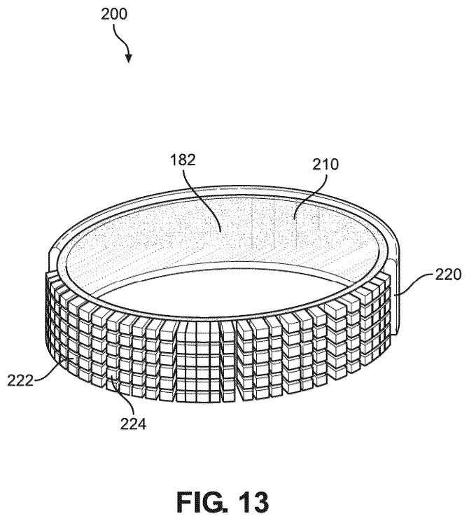

FIG. 13 shows a front perspective view of a head band 200 of a system for utilizing a plurality of heating and cooling pads 100.

The head band 200 may be placed around a user's neck to facilitate cooling and/or warming up a user's neck while being worn by the user.

The head band 200 may include an interior band portion 210 and an exterior bank portion 220.

The interior band portion 210 may include the one or more cooling and heating pads 184 (a different shape of the cooling and heating pads 130) that may be disposed on a headband 192 within the helmet 190 to facilitate cooling a user's head while being worn by the user, or that may be disposed on the head band 200 to facilitate cooling or warming up a user's neck while being worn by the user.

The exterior back portion 220 may include a decorate jewel portion 222 having a plurality of jewels 224 or other decorate material disposed on the exterior back portion 220 to be aesthetically pleasing to the user.

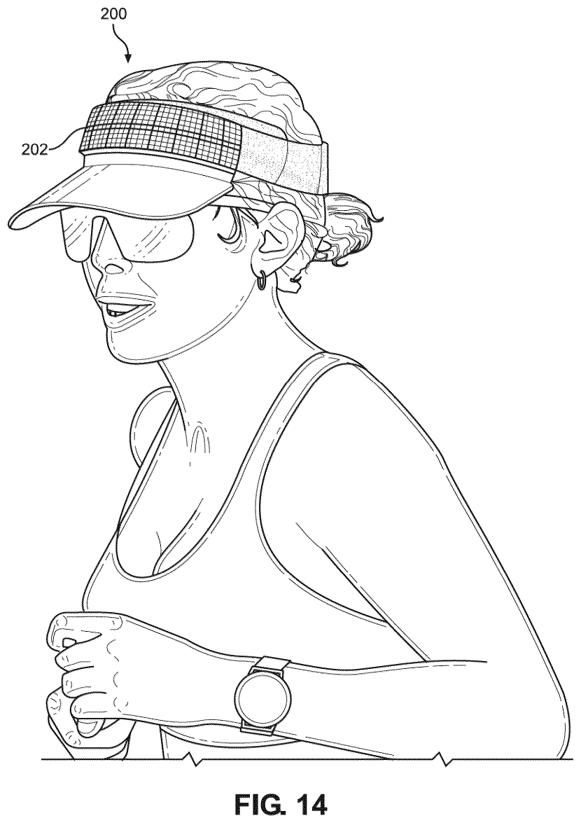

FIG. 14 shows an environmental side perspective view of a head band 200 of a system for utilizing a plurality of heating and cooling pads 100.

The head band 200 may be disposed above a visor 202 or the like to keep a user's head relatively cool and comfortable in relatively warm or hot weather. The head band 200 may be disposed around a user's neck (not shown) or the like.

It is therefore submitted that the present invention has been shown and described in what is the most practical and preferred embodiments. It is recognized, however, that departures may be made within the scope of the present invention and that obvious modifications will occur to a person skilled in the art. With respect to the above description then, it is to be realized that the optimum dimensional relationships for the parts of the present invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention. Further, since numerous modifications and changes will readily occur to those skilled in the art, it is not desired to limit the present invention to the exact construction and operation shown and described, and accordingly, all suitable modifications and equivalents may be resorted to, falling within the scope of the present invention.

Therefore, the foregoing is considered as illustrative only of the principles of the present invention. Further, since numerous modifications and changes will readily occur to those skilled in the art, it is not desired to limit the present invention to the exact construction and operation shown and described, and accordingly, all suitable modifications and equivalents may be resorted to, falling within the scope of the present invention.

I claim:

1. A system for utilizing a plurality of heating and cooling pads, comprising:
a plurality of mobile applications;
wherein the mobile applications include a plurality of mobile and cloud-based applications;
a smart battery pack having a plurality of internal components; and
one or more heating and cooling pads;
wherein the one or more heating and cooling pads wirelessly communicate with the mobile applications;
wherein the smart battery pack works as an intermediary relaying data exchanged between the one or more connected heating and cooling pads and the mobile applications; and
wherein the smart battery pack supplies power to the one or more connected heating and cooling pads.

2. The system for utilizing a plurality of heating and cooling pads, according to claim 1, wherein the mobile applications are selected from the group consisting of a plurality of smart phone mobile apps, a plurality of smart watch apps, or a plurality of cloud-based apps.

3. The system for utilizing a plurality of heating and cooling pads, according to claim 1, wherein the internal components include a microcontroller and wireless communication module, a mobile wireless scope, a sensor wherein the sensor is a temperature sensor, a battery wherein the battery is a rechargeable battery, an inertial measurement unit wherein the inertial measurement unit includes a gyroscope, an accelerometer, and a magnetometer, a Global Positioning System the Global Positioning System provides precise location and time information regarding the one or more heating and cooling pads, and one or more communication lines electrically communicating with the mobile applications.

4. The system for utilizing a plurality of heating and cooling pads, according to claim 1, wherein the smart battery pack is in wired connection with the one or more heating and cooling pads to supply electrical power to the one or more heating and cooling pads.

5. The system for utilizing a plurality of heating and cooling pads, according to claim 1, wherein the mobile applications monitor and control the one or more heating and cooling pads.

6. The system for utilizing a plurality of heating and cooling pads, according to claim 1, wherein the one or more heating and cooling pads includes a control and communication unit, a flexible thermoelectric device, a power and communication socket, a battery holder, a proprietary power and communication connector, and a plurality of connecting pads.

7. The system for utilizing a plurality of heating and cooling pads, according to claim 6, wherein the control and communication unit includes a communication module and a central processing unit to control heating and cooling performance and thermal performance of the flexible thermoelectric device.

8. The system for utilizing a plurality of heating and cooling pads, according to claim 6, wherein the flexible thermoelectric device is disposed on top of each of the one or more first heating and cooling pads.

9. The system for utilizing a plurality of heating and cooling pads, according to claim 6, wherein the proprietary power and communication connector is disposed on the control and communication module.

10. The system for utilizing a plurality of heating and cooling pads, according to claim 6, wherein the connecting pads are disposed on the proprietary power and communication connector.

11. The system for utilizing a plurality of heating and cooling pads, according to claim 6, wherein the battery holder is equipped on the one or more first heating and cooling pads and contains a rechargeable battery.

12. The system for utilizing a plurality of heating and cooling pads, according to claim 6, wherein the one or more first heating and cooling pads are in a standalone configuration.

13. The system for utilizing a plurality of heating and cooling pads, according to claim 6, wherein the one or more first heating and cooling pads are in a meshed configuration powered by the smart battery pack.

14. The system for utilizing a plurality of heating and cooling pads, according to claim 6, wherein the one or more heating and cooling pads are in wireless communication with the mobile applications, allowing the mobile applications to monitor temperature and other sensor data and control the thermal performance of the one or more heating and cooling pads based on user preference.

15. The system for utilizing a plurality of heating and cooling pads, according to claim 1, further comprising a first mobile user interface that includes a monitoring mobile user interface and a control mobile interface.

16. The system for utilizing a plurality of heating and cooling pads, according to claim 1, further comprising a second mobile user interfaces that includes the first mobile user interfaces, except the second mobile user interfaces are disposed on various items that include a piece of clothing.

17. The system for utilizing a plurality of heating and cooling pads, according to claim 1, further comprising a plurality of proprietary mobile and cloud-based applications wirelessly communicating with the heating and cooling pads.

18. The system for utilizing a plurality of heating and cooling pads, according to claim 1, further comprising a virtual reality headset that includes a back handle and one or more cooling pads that cools down a user's forehead and eyes and would improve a user's comfort and user experience.

19. The system for utilizing a plurality of heating and cooling pads, according to claim 18, further comprising a helmet that includes the one or more cooling pads disposed directly onto the outer surface of the helmet to facilitate cooling a user's head while being worn by the user.

20. The system for utilizing a plurality of heating and cooling pads, according to claim 1, further comprising head band that is placed around a user's neck to facilitate cooling or warming the user's neck while being worn by the user; and wherein the head band is disposed above a visor to keep a user's head relatively cool and comfortable.
